(19) United States
(12) Patent Application Publication
(10) Pub. No.: US 2026/0040679 A1
(43) Pub. Date: Feb. 5, 2026

(54) SEMICONDUCTOR DEVICE

(71) Applicant: Samsung Electronics Co., Ltd., Suwon-si (KR)

(72) Inventors: Soo Jin JEONG, Suwon-si (KR); Myung Gil KANG, Suwon-si (KR); Wook Hyun KWON, Suwon-si (KR); Bum Cheol KIM, Suwon-si (KR); Hyun Min AHN, Suwon-si (KR); Byoung Hak HONG, Suwon-si (KR)

(21) Appl. No.: 19/074,673

(22) Filed: Mar. 10, 2025

(30) Foreign Application Priority Data
Aug. 5, 2024 (KR) 10-2024-0103721

(51) Int. Cl. H10D 84/85; H10D 84/01

(52) U.S. Cl. CPC H10D 84/856; H10D 84/0167; H10D 84/0184; H10D 84/851

(57) ABSTRACT

Semiconductor devices including a substrate, first and second active patterns, the first and second active patterns spaced apart, a second width of the second active pattern greater than a first width of the first active pattern, a first plurality of nanosheets stacked and spaced apart from each other on the first active pattern, a second plurality of nanosheets spaced apart from each other on the second active pattern, a second width of the second plurality of nanosheets greater than a first width of the first plurality of nanosheets, a gate electrode surrounding the first and second plurality of nanosheets, a first inner spacer on both sidewalls of the gate electrode between adjacent first plurality of nanosheets, and a second inner spacer on both sidewalls of the gate electrode between adjacent second plurality of nanosheets, a thickness of the second inner spacer smaller than a thickness of the first inner spacer.

### CROSS-REFERENCE TO RELATED APPLICATION

This U.S. non-provisional application claims priority from Korean Patent Application No. 10-2024-0103721, filed on Aug. 5, 2024, in the Korean Intellectual Property Office, and all the benefits accruing therefrom under 35 U.S.C. § 119, the contents of which in its entirety are herein incorporated by reference.

### BACKGROUND

### 1. Technical Field

Various exemplary embodiments relate to a semiconductor device. Specifically, the present disclosure relates to a semiconductor device including a MBCFET™ (Multi-Bridge Channel Field Effect Transistor).

### 2. Description of the Related Art

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Because these multi-gate transistors utilize a three-dimensional channel, they are easy to scale. Additionally, the current control capability may be improved without increasing the gate length of the multi-gate transistor. Furthermore, the SCE (short channel effect), in which the potential of the channel region is influenced by the drain voltage, may be effectively suppressed.

### SUMMARY

The present disclosure may provide a semiconductor device that improves reliability by forming different widths of an inner spacer formed on an NMOS (N-type metal-oxide-semiconductor) transistor and an inner spacer formed on a PMOS (P-channel metal-oxide0semiconductor) transistor.

The aspects of the present invention are not limited to those mentioned herein and another aspect which is not mentioned may be clearly understood by those skilled in the art from the description below.

According to some embodiments of the present disclosure, there is provided a semiconductor device, comprising a substrate, a first active pattern extending in a first horizontal direction on the substrate, a second active pattern extending in the first horizontal direction on the substrate, the second active pattern being spaced apart from the first active pattern in a second horizontal direction different from the first horizontal direction, a second width of the second active pattern in the second horizontal direction being greater than a first width of the first active pattern in the second horizontal direction, a first plurality of nanosheets, each nanosheet of the first plurality of nanosheets being stacked and spaced apart from each other in a vertical direction on the first active pattern, a second plurality of nanosheets, each nanosheet of the second plurality of nanosheets being spaced apart from each other in the vertical direction on the second active pattern, a second width of each nanosheet of the second plurality of nanosheets in the second horizontal direction being greater than a first width of each nanosheet of the first plurality of nanosheets in the second horizontal direction, a gate electrode extending in the second horizontal direction on the first and second active patterns, the gate electrode extending surrounding each nanosheet of the first plurality of nanosheets and each nanosheet of the second plurality of nanosheets, the gate electrode having two sidewalls, a first inner spacer disposed on both of the two sidewalls of the gate electrode in the first horizontal direction between adjacent nanosheets of the first plurality of nanosheets, and a second inner spacer disposed on both sidewalls of the gate electrode in the first horizontal direction between adjacent nanosheets of the second plurality of nanosheets, a second thickness of the second inner spacer in the first horizontal direction being smaller than a first thickness of the first inner spacer in the first horizontal direction.

According to some embodiments of the present disclosure, there is provided a semiconductor device, comprising a substrate, a first active pattern extending in a first horizontal direction on the substrate, a second active pattern extending in the first horizontal direction on the substrate, the second active pattern being spaced apart from the first active pattern in a second horizontal direction different from the first horizontal direction, a first plurality of nanosheets, each nanosheet of the first plurality of nanosheets being stacked and spaced apart from each other in a vertical direction on the first active pattern, each nanosheet of the first plurality of nanosheets having two sidewalls, a second plurality of nanosheets, each nanosheet of the second plurality of nanosheets being stacked and spaced apart from each other in the vertical direction on the second active pattern, a second width of each nanosheet of the second plurality of nanosheets in the second horizontal direction being greater than a first width of each nanosheet of the first plurality of nanosheets in the second horizontal direction, each nanosheet of the second plurality of nanosheets having two sidewalls, a gate electrode extending in the second horizontal direction on the first and second active patterns, the gate electrode surrounding each nanosheet of the first plurality of nanosheets and each nanosheet of the second plurality of nanosheets, the gate electrode having two sidewalls, a first source/drain region being in contact with both of the two sidewalls in the first horizontal direction of each nanosheet of the first plurality of nanosheets on the first active pattern, a second source/drain region being in contact with both of the two sidewalls in the first horizontal direction of each nanosheet of the second plurality of nanosheets on the second active pattern, a first inner spacer disposed between the gate electrode and the first source/drain region, and a second inner spacer disposed between the gate electrode and the second source/drain region, wherein a first portion of the first inner spacer overlaps with the second inner spacer in the second horizontal direction, and a second portion of the first inner spacer does not overlap with the second inner spacer in the second horizontal direction.

According to some embodiments of the present disclosure, there is provided a semiconductor device, comprising a substrate, a first active pattern extending in a first horizontal direction on the substrate, a second active pattern extending in the first horizontal direction on the substrate, the second active pattern being spaced apart from the first active pattern in a second horizontal direction different from the first horizontal direction, a second width of the second active pattern in the second horizontal direction greater than a first width of the first active pattern in the second horizontal direction, a first plurality of nanosheets, each nanosheet of the first plurality of nanosheets being stacked and spaced apart from each other in a vertical direction on the first active pattern, each nanosheet of the first plurality of nanosheets having two sidewalls, a second plurality of nanosheets, each nanosheet of the second plurality of nanosheets being stacked and spaced apart from each other in the vertical direction on the second active pattern, a second width of each nanosheet of the second plurality of nanosheets in the second horizontal direction greater than a first width of each nanosheet of the first plurality of nanosheets in the second horizontal direction, each nanosheet of the second plurality of nanosheets having two sidewalls, a gate electrode extending in the second horizontal direction on the first and second active patterns, the gate electrode surrounding each nanosheet of the first plurality of nanosheets and each nanosheet of the second plurality of nanosheets, a first source/drain region being in contact with both of the two sidewalls in the first horizontal direction of each nanosheet of the first plurality of nanosheets on the first active pattern, a second source/drain region being in contact with both of the two sidewalls in the first horizontal direction of each nanosheet of the second plurality of nanosheets on the second active pattern, a first inner spacer disposed between the gate electrode and the first source/drain region, a second inner spacer disposed between the gate electrode and the second source/drain region, a second thickness of the second inner spacer in the first horizontal direction being smaller than a first thickness of the first inner spacer in the first horizontal direction, a second width of the second inner spacer in the second horizontal direction being greater than a first width of the first inner spacer in the second horizontal direction, and a gate spacer disposed on both of the two sidewalls in the first horizontal direction of the gate electrode on a first upper surface of an uppermost nanosheet of the first plurality of nanosheets and on a second upper surface of an uppermost nanosheet of the second plurality of nanosheets, wherein the first and second thicknesses of each of the first and second inner spacers in the first horizontal direction are each smaller than a thickness of the gate spacer in the first horizontal direction, and wherein a first portion of the first inner spacer overlaps with the second inner spacer in the second horizontal direction, and a second portion of the first inner spacer does not overlap with the second inner spacer in the second horizontal direction.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a layout diagram for explaining a semiconductor device according to some exemplary embodiments of the present disclosure;

FIG. 2 is a cross-sectional view taken along the line A-A′ of FIG. 1;

FIG. 3 is a cross-sectional view taken along the line B-B′ of FIG. 1;

FIG. 4 is a cross-sectional view taken along the line C-C′ of FIG. 1;

FIGS. 5 to 22 are intermediate stage diagrams for explaining the fabrication methods of semiconductor devices according to some exemplary embodiments of the present disclosure;

FIG. 23 is a layout diagram for explaining a semiconductor device according to some exemplary embodiments of the present disclosure;

FIG. 24 is a cross-sectional view taken along the line D-D′ of FIG. 23;

FIG. 25 is a cross-sectional view taken along the line E-E′ of FIG. 23;

FIG. 26 is a layout diagram for explaining a semiconductor device according to some other exemplary embodiments of the present disclosure;

FIG. 27 is a cross-sectional view taken along the line F-F′ of FIG. 26;

FIG. 28 is a cross-sectional view taken along the line G-G′ of FIG. 26;

FIG. 29 is a layout diagram for explaining a semiconductor device according to another exemplary embodiments of the present disclosure;

FIG. 30 is a cross-sectional view taken along the line H-H′ of FIG. 29;

FIG. 31 is a cross-sectional view taken along the line I-I′ of FIG. 29;

FIG. 32 is a layout diagram for explaining a semiconductor device according to another exemplary embodiments of the present disclosure;

FIG. 33 is a cross-sectional view taken along the line J-J′ of FIG. 32; and

FIG. 34 is a cross-sectional view taken along the line K-K′ of FIG. 32.

### DETAILED DESCRIPTION OF THE EMBODIMENTS

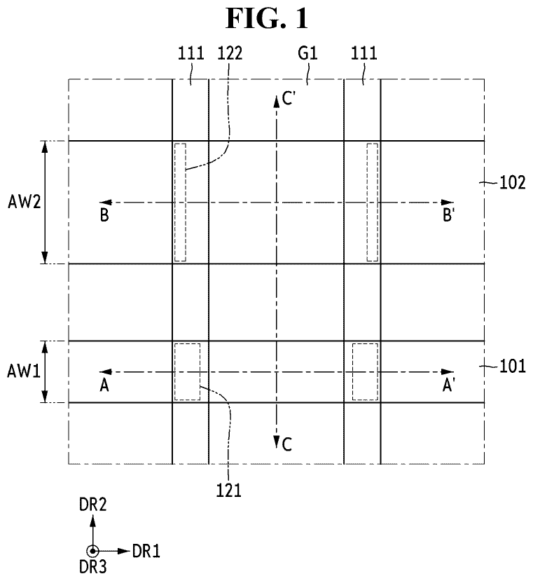

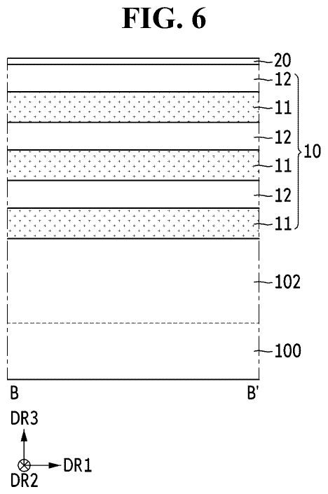

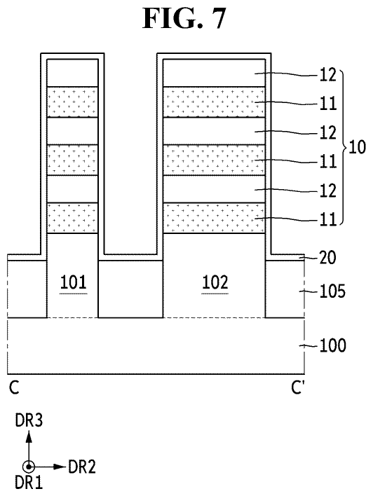

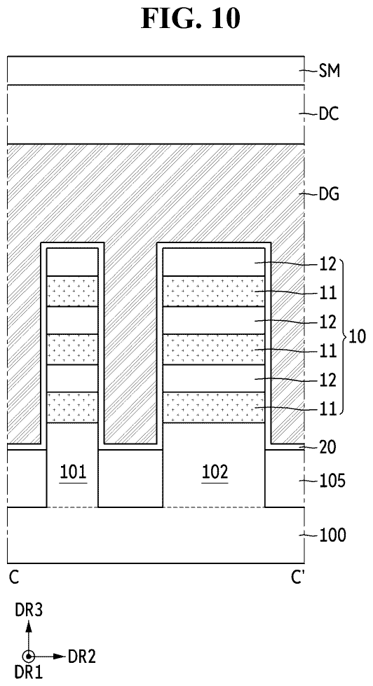

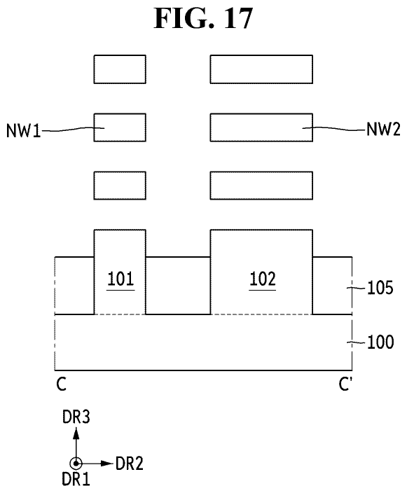

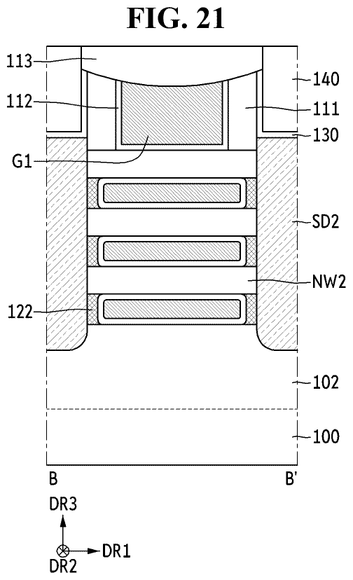

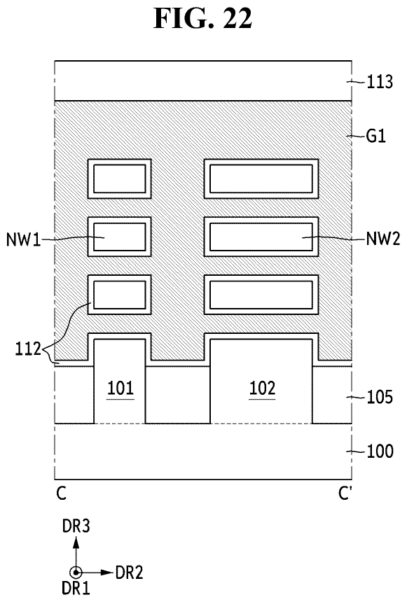

Hereinafter, a semiconductor device according to some exemplary embodiments of the present disclosure will be described with reference to FIGS. 1 to 34.

The invention may be embodied in many different forms and should not be construed as limited to the example embodiments set forth herein. These example embodiments are just that—examples—and many implementations and variations are possible that do not require the details provided herein. The disclosure provides details of alternative examples, but such listing of alternatives is not exhaustive.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise.

Spatially relative terms, such as “above,” “bottom,” “vertical”, “horizontal” and the like, may be used herein for ease of description to describe positional relationships, such as illustrated in the figures, for example. It will be understood that the spatially relative terms encompass different orientations, in addition to the orientation depicted in the figures.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

As used herein, the words “surround” and “surrounding” and “surrounded” are intended to mean that an element is outside the other element. The elements may be touching or not. The surrounding element may or may not completely surround an inner element. The surrounding element does not need to completely surround the inner element, however. As used herein, the term “adjacent” may be used to mean that an element is near another element. The two elements need not be touching or directly contacting one another. As used herein the terms “on”, “over”, “covering” or “overlapping” are intended to mean that an element is over or aside another element. The elements may be touching or not. For example, there may be layers between layers that are “on” one another. An element “on” or “over” or “stacked” over or “covering” or “overlapping” another element need not cover an entire top surface of an element below to be considered “on” or “over” or “stacked” over or “covering” or “overlapping”. The terms are intended to encompass one element “on” or “over” or “stacked” over or “covering” or “overlapping” all, or any part of, an element below it.

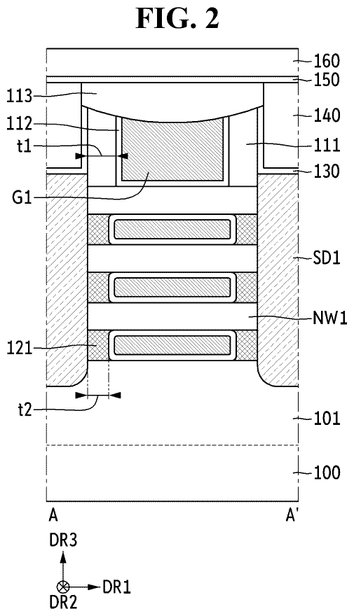

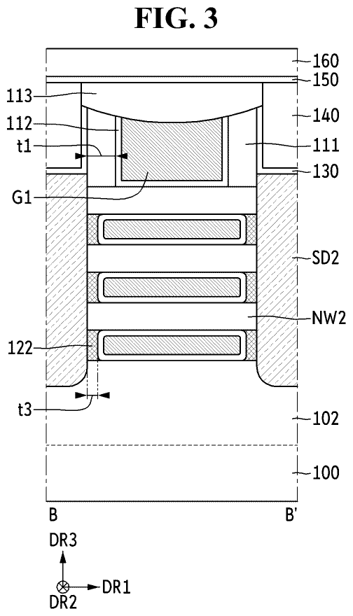

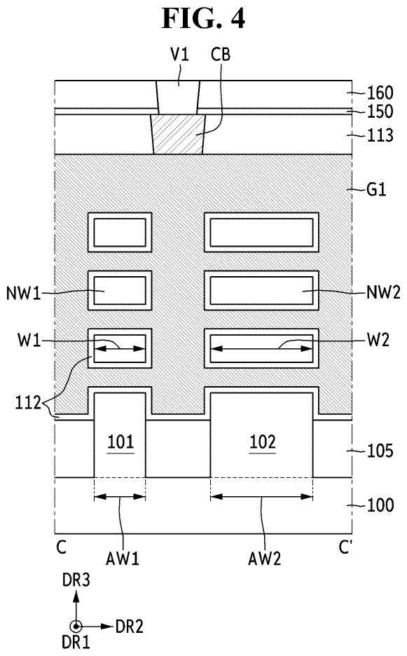

FIG. 1 is a layout diagram for explaining a semiconductor device according to some exemplary embodiments of the present disclosure. FIG. 2 is a cross-sectional view taken along line A-A′ of FIG. 1. FIG. 3 is a cross-sectional view taken along the line B-B′ of FIG. 1. FIG. 4 is a cross-sectional view taken along the line C-C′ of FIG. 1.

The semiconductor device may be a semiconductor chip (i.e., a semiconductor die singulated from (e.g., cut from) a wafer).

Referring to FIGS. 1 to 4, the semiconductor device according to some exemplary embodiments of the present disclosure includes a substrate 100, first and second active patterns 101, 102, a field insulating layer 105, first and second pluralities of nanosheets NW1, NW2, a gate electrode G1, a gate spacer 111, a gate insulating layer 112, a capping pattern 113, first and second source/drain regions SD1, SD2, first and second inner spacers 121, 122, a first etching stop layer 130, a first interlayer insulating layer 140, a gate contact CB, a second etching stop layer 150, a second interlayer insulating layer 160, and a via V1.

The substrate 100 may be a silicon substrate or SOI (silicon-on-insulator). Alternatively, the substrate 100 may include silicon germanium, SGOI (silicon germanium on insulator), indium antimonide, lead telluride compounds, indium arsenide, indium phosphide, gallium arsenide, or gallium antimonide, but the present invention is not limited thereto. In the following, each of the first horizontal direction DR1 and the second horizontal direction DR2 may be defined as a direction parallel to an upper surface of the substrate 100. The second horizontal direction DR2 may be defined as a direction different from the first horizontal direction DR1. The vertical direction DR3 may be defined as a direction perpendicular to each of the first horizontal direction DR1 and the second horizontal direction DR2. The vertical direction DR3 may be defined as a direction perpendicular to the upper surface of the substrate 100.

Each of the first and second active patterns 101, 102 may extend in the first horizontal direction DR1 on an upper surface of the substrate 100. The second active pattern 102 may be spaced apart from the first active pattern 101 in the second horizontal direction DR2. In some examples, the second width AW2 of the second active pattern 102 in the second horizontal direction DR2 may be greater than the first width AW1 of the first active pattern 101 in the second horizontal direction DR2. Each of the first and second active patterns 101, 102 may protrude in the vertical direction DR3 from the upper surface of the substrate 100. In some examples, each of the first and second active patterns 101, 102 may be a portion of the substrate 100, or may include an epitaxial layer grown from the substrate 100.

The field insulating layer 105 may be disposed on the upper surface of the substrate 100. The field insulating layer 105 may surround the sidewall of each of the first and second active patterns 101, 102. In some examples, the upper surface of each of the first and second active patterns 101, 102 may protrude in a vertical direction DR3 than the upper surface of the field insulating layer 105. However, the present invention is not limited thereto. In some other exemplary embodiments, the upper surface of each of the first and second active patterns 101, 102 may be formed on the same plane as the upper surface of the field insulating layer 105. The field insulating layer 105 may include, for example, an oxide layer, a nitride layer, an oxynitride layer, or a combination thereof.

A first plurality of nanosheets NW1 may be disposed on the first active pattern 101. The first plurality of nanosheets NW1 may include a plurality of nanosheets stacked and spaced apart from each other in the vertical direction DR3 on the first active pattern 101. A second plurality of nanosheets NW2 may be disposed on the second active pattern 102. The second plurality of nanosheets NW2 may be spaced apart from the first plurality of nanosheets NW1 in the second horizontal direction DR2. In some examples, the second width W2 of the second plurality of nanosheets NW2 in the second horizontal direction DR2 may be greater than the first width W1 of the first plurality of nanosheets NW1 in the second horizontal direction DR2. The second plurality of nanosheets NW2 may include a plurality of nanosheets stacked and spaced apart from each other in the vertical direction DR3 on the second active pattern 102. In some examples, each of the nanosheets included in the second plurality of nanosheets NW2 may be disposed at the same vertical level as each of the nanosheets included in the first plurality of nanosheets NW1.

In FIGS. 2 to 4, each of the first plurality of nanosheets NW1 and the second plurality of nanosheets NW2 is shown as including three nanosheets stacked and spaced apart from each other in the vertical direction DR3, but this is for convenience of explanation, and the present invention is not limited thereto. In some other exemplary embodiments, each of the first plurality of nanosheets NW1 and the second plurality of nanosheets NW2 may include four or more nanosheets stacked and spaced apart from each other in the vertical direction DR3. In some examples, each of the first and second plurality of nanosheets NW1, NW2 may include silicon (Si). However, the present invention is not limited thereto. In some other exemplary embodiments, each of the first and second plurality of nanosheets NW1, NW2 may be silicon germanium (SiGe).

The gate electrode G1 may extend in the second horizontal direction DR2 on the first active pattern 101, the second active pattern 102, and the field insulating layer 105. The gate electrode G1 may surround both the first plurality of nanosheets NW1 and the second plurality of nanosheets NW2, and optionally one or more additional pluralities of nanosheets provided herein. In some examples, the width of the gate electrode G1 in the first horizontal direction DR1 between the uppermost surface of the second active pattern 102 and the bottom surface of the lowermost nanosheet of the second plurality of nanosheets NW2 may be greater than the width of the gate electrode G1 in the first horizontal direction DR1 between the uppermost surface of the first active pattern 101 and the bottom surface of the lowermost nanosheet of the first plurality of nanosheets NW1. Further, the width of the gate electrode G1 in the first horizontal direction DR1 between adjacent the second plurality of nanosheets NW2 may be greater than the width of the gate electrode G1 in the first horizontal direction DR1 between adjacent the first plurality of nanosheets NW1.

In some examples, the gate electrode G1 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAIC-N), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. The gate electrode G1 may include a conductive metal oxide, a conductive metal oxynitride, etc., and may include the oxidized forms of the aforementioned materials.

The gate electrode G1 may include e.g. two sidewalls and the gate spacer 111 may be disposed on both of the two sidewalls of the gate electrode G1 in the first horizontal direction DR1 on the upper surfaces of both of the uppermost nanosheets of each of the first and second pluralities of nanosheets NW1, NW2 and on the upper surface of the field insulating layer 105. The gate spacer 111 may extend in the second horizontal direction DR2 along both of the two sidewalls of the gate electrode G1 in the first horizontal direction DR1. In some examples, the gate spacer 111 may be in contact with the upper surfaces of both of the uppermost nanosheets of each of the first and second plurality of nanosheets NW1, NW2. In some examples, the gate spacer 111 may include at least one of silicon nitride (SiN), silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon oxycarbide (SiOC), or combinations thereof. However, the present invention is not limited thereto.

The first source/drain region SD1 may be disposed on both of the two sidewalls of the gate electrode G1 in the first horizontal direction DR1 on the first active pattern 101. In some examples, the first plurality of nanosheets NW1 may include two sidewalls for each nanosheet of the plurality of nanosheets NW1, and the first source/drain region SD1 may be in contact with both of the two sidewalls of each nanosheet of the first plurality of nanosheets NW1 in the first horizontal direction DR1. The second source/drain region SD2 may be disposed on both of the two sidewalls of the gate electrode G1 in the first horizontal direction DR1 on the second active pattern 102. In some examples, the second plurality of nanosheets NW2 may include two sidewalls for each nanosheet of the plurality of nanosheets NW2, and the second source/drain region SD2 may be in contact with both of the two sidewalls of each nanosheet of the second plurality of nanosheets NW2 in the first horizontal direction DR1.

In some examples, the upper surface of the first source/drain region SD1 may be formed higher than the upper surface of the uppermost nanosheet of the first plurality of nanosheets NW1. Further, the upper surface of the second source/drain region SD2 may be formed higher than the upper surface of the uppermost nanosheet of the second plurality of nanosheets NW2. Although not shown, the second source/drain region SD2 may be spaced apart from the first source/drain region SD1 in the second horizontal direction DR2. In some examples, the second width of the second source/drain region SD2 in the second horizontal direction DR2 may be greater than the first width of the first source/drain region SD1 in the second horizontal direction DR2.

In some exemplary embodiments, the first plurality of nanosheets NW1, the gate electrode G1, and the first source/drain region SD1 may form an NMOS transistor. Further, the second plurality of nanosheets NW2, the gate electrode G1, and the second source/drain region SD2 may form a PMOS transistor. In some other exemplary embodiments, the first plurality of nanosheets NW1, the gate electrode G1, and the first source/drain region SD1 may form a PMOS transistor. Further, the second plurality of nanosheets NW2, the gate electrode G1, and the second source/drain region SD2 may form an NMOS transistor.

The first inner spacer 121 may be disposed between the gate electrode G1 and the first source/drain region SD1. In some examples, the first inner spacer 121 may be in contact with the first source/drain region SD1. The first inner spacer 121 may be disposed on both of the two sidewalls of the gate electrode G1 in the first horizontal direction DR1 between the uppermost surface of the first active pattern 101 and the bottom surface of the lowermost nanosheet of the first plurality of nanosheets NW1. The first inner spacer 121 may be disposed on both of the two sidewalls of the gate electrode G1 in the first horizontal direction DR1 between adjacent the first plurality of nanosheets NW1.

In some examples, the sidewall of the first inner spacer 121 in the first horizontal direction DR1 facing the gate electrode G1 may be concavely formed toward the first source/drain region SD1. In FIG. 2, it is shown that the sidewall of the first inner spacer 121 in the first horizontal direction DR1 that is in contact with the first source/drain region SD1 is aligned with the sidewall of the first plurality of nanosheets NW1 in the first horizontal direction DR1, but the present invention is not limited thereto. In some other exemplary embodiments, the sidewall of the first inner spacer 121 in the first horizontal direction DR1 that is in contact with the first source/drain region SD1 may be concavely formed toward the gate electrode G1.

The second inner spacer 122 may be disposed between the gate electrode G1 and the second source/drain region SD2. In some examples, the second inner spacer 122 may be in contact with the second source/drain region SD2. The second inner spacer 122 may be disposed on both of the two sidewalls of the gate electrode G1 in the first horizontal direction DR1 between the uppermost surface of the second active pattern 102 and the bottom surface of the lowermost nanosheet of the second plurality of nanosheets NW2. The second inner spacer 122 may be disposed on both of the two sidewalls of the gate electrode G1 in the first horizontal direction DR1 between adjacent the second plurality of nanosheets NW2.

In some examples, the sidewall of the second inner spacer 122 in the first horizontal direction DR1 facing the gate electrode G1 may be concavely formed toward the second source/drain region SD2. In FIG. 3, it is shown that the sidewall of the second inner spacer 122 in the first horizontal direction DR1 that is in contact with the second source/drain region SD2 is aligned with the sidewall of the second plurality of nanosheets NW2 in the first horizontal direction DR1, but the present invention is not limited thereto. In some other exemplary embodiments, the sidewall of the second inner spacer 122 in the first horizontal direction DR1 that is in contact with the second source/drain region SD2 may be concavely formed toward the gate electrode G1.

In some examples, the first thickness t2 of the first inner spacer 121 in the first horizontal direction DR1 may be smaller than the thickness t1 of the gate spacer 111 in the first horizontal direction DR1 disposed on one side of the gate electrode G1. In some examples, the second thickness t3 of the second inner spacer 122 in the first horizontal direction DR1 may be smaller than the thickness t1 of the gate spacer 111 in the first horizontal direction DR1 disposed on one side of the gate electrode G1. In some examples, the second thickness t3 of the second inner spacer 122 in the first horizontal direction DR1 may be smaller than the first thickness t2 of the first inner spacer 121 in the first horizontal direction DR1. In some examples, the second width of the second inner spacer 122 in the second horizontal direction DR2 may be greater than the first width of the first inner spacer 121 in the second horizontal direction DR2.

In some examples, the first inner spacer may be a plurality of first inner spacers and the second inner spacer may be a plurality of second inner spacers. In some examples, the second width in the first horizontal direction DR1 between the second inner spacers 122 may be greater than the first width in the first horizontal direction DR1 between the first inner spacers 121. In some examples, a first portion of the first inner spacer 121 may overlap with the second inner spacer 122 in the second horizontal direction DR2. In some examples, a second portion of the first inner spacer 121 may not overlap with the second inner spacer 122 in the second horizontal direction DR2. This is because the second thickness t3 of the second inner spacer 122 in the first horizontal direction DR1 is smaller than the first thickness t2 of the first inner spacer 121 in the first horizontal direction DR1. In some examples, each of the first and second inner spacers 121, 122 may include at least one of silicon nitride (SiN), silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon oxycarbide (SiOC), or combinations thereof. However, the present invention is not limited thereto.

The gate insulating layer 112 may be disposed between the gate electrode G1 and the gate spacer 111. The gate insulating layer 112 may be disposed between the gate electrode G1 and the first active pattern 101. The gate insulating layer 112 may be disposed between the gate electrode G1 and the second active pattern 102. The gate insulating layer 112 may be disposed between the gate electrode G1 and the field insulating layer 105. The gate insulating layer 112 may be disposed between the gate electrode G1 and the first plurality of nanosheets NW1. The gate insulating layer 112 may be disposed between the gate electrode G1 and the second plurality of nanosheets NW2. The gate insulating layer 112 may be disposed between the gate electrode G1 and the first inner spacer 121. The gate insulating layer 112 may be disposed between the gate electrode G1 and the second inner spacer 122. In some examples, the gate insulating layer 112 may be in contact with each of the first and second inner spacers 121, 122. In some examples, the gate insulating layer 112 may be spaced apart from each of the first and second source/drain regions SD1, SD2 in the first horizontal direction DR1.

In some examples, the gate insulating layer 112 may include at least one of silicon oxide, silicon oxynitride, silicon nitride, or a high-k dielectric material with a dielectric constant greater than that of silicon oxide. High-k dielectric materials may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some exemplary embodiments may include an NC (Negative Capacitance) FET utilizing a negative capacitor. In some examples, the gate insulating layer 112 may include a ferroelectric material layer having ferroelectric properties and a paraelectric material layer having paraelectric properties.

The ferroelectric material layer may have a negative capacitance, while the paraelectric material layer may have a positive capacitance. In some examples, when two or more capacitors are connected in series and each of their capacitances has a positive value, the overall capacitance is reduced compared to the capacitance of each individual capacitor. On the other hand, when at least one of the capacitances of the two or more capacitors connected in series has a negative value, the overall capacitance may have a positive value and be greater than the absolute value of each individual capacitance.

When the ferroelectric material layer having a negative capacitance and the paraelectric material layer having a positive capacitance are connected in series, the overall capacitance value of the ferroelectric material layer and the paraelectric material layer connected in series may increase. By utilizing the increase in overall capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, or lead zirconium titanium oxide. As another example, hafnium zirconium oxide may be a material in which zirconium (Zr) is doped into hafnium oxide. In another exemplary, hafnium zirconium oxide may be a compound of hafnium (Hf) and zirconium (Zr) with oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The type of dopant included in the ferroelectric material layer may vary depending on the specific ferroelectric material included in the ferroelectric material layer.

When the ferroelectric material layer includes hafnium oxide, the dopant included in the ferroelectric material layer may include, for example, at least one of gadolinium (Gd), silicon (Si), zirconium (Zr), aluminum (Al), or yttrium (Y).

When the dopant is aluminum (Al), the ferroelectric material layer may contain 3 to 8 at % (atomic %) of aluminum. Here, the proportion of the dopant may be a ratio of aluminum to the sum of hafnium and aluminum.

When the dopant is silicon (Si), the ferroelectric material layer may include 2 to 10 at % of silicon. When the dopant is yttrium (Y), the ferroelectric material layer may include 2 to 10 at % of yttrium. When the dopant is gadolinium (Gd), the ferroelectric material layer may include 1 to 7 at % of gadolinium. When the dopant is zirconium (Zr), the ferroelectric material layer may include 50 to 80 at % of zirconium.

The paraelectric material layer may have paraelectric properties. The paraelectric material layer may include, for example, at least one of silicon oxide or a high-k metal oxide. The metal oxide included in the paraelectric material layer may include, for example, at least one of hafnium oxide, zirconium oxide, or aluminum oxide, but is not limited thereto.

The ferroelectric material layer and the paraelectric material layer may include the same material. While the ferroelectric material layer may have ferroelectric properties, the paraelectric material layer may not have ferroelectric properties. In some examples, when the ferroelectric material layer and the paraelectric material layer include hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. The thickness of the ferroelectric material layer may be, for example, 0.5 to 10 nm, but is not limited thereto. Because each ferroelectric material may have a different critical thickness for exhibiting ferroelectric properties, the thickness of the ferroelectric material layer may vary depending on the specific ferroelectric material.

In some examples, the gate insulating layer 112 may include a single ferroelectric material layer. In another example, the gate insulating layer 112 may include a plurality of ferroelectric material layers spaced apart from each other. The gate insulating layer 112 may have a stacked layer structure in which the plurality of ferroelectric material layers are alternately stacked with the plurality of paraelectric material layers.

The first etching stop layer 130 may be disposed on the sidewall of the gate spacer 111 in the first horizontal direction DR1. The first etching stop layer 130 may be disposed on the upper surface of each of the first and second source/drain regions SD1, SD2. Although not shown, the first etching stop layer 130 may be disposed on the upper surface of the field insulating layer 105. Additionally, although not shown, the first etching stop layer 130 may be disposed on both sidewalls of the first and second source/drain regions SD1, SD2 in the second horizontal direction DR2. In some examples, the first etching stop layer 130 may be formed conformally. The first etching stop layer 130, for example, may include at least one of aluminum oxide, aluminum nitride, hafnium oxide, zirconium oxide, silicon oxide, silicon nitride, silicon oxynitride, or a low-k dielectric material.

The capping pattern 113 may extend in the second horizontal direction DR2 on each of the gate spacer 111, the gate insulating layer 112, the gate electrode G1, and the first etching stop layer 130. In some examples, the bottom surface of the capping pattern 113 may be in contact with the first etching stop layer 130. However, the present invention is not limited thereto. In some other exemplary embodiments, the sidewall of the capping pattern 113 may be in contact with the first etching stop layer 130. The capping pattern 113 may include, for example, at least one of silicon nitride (SiN), silicon oxynitride (SiON), silicon oxide (SiO₂), silicon carbonitride (SiCN), silicon oxycarbonitride (SiOCN), or combinations thereof. However, the present invention is not limited thereto.

The first interlayer insulating layer 140 may be disposed on the first etching stop layer 130. The first interlayer insulating layer 140 may surround the sidewalls of the capping pattern 113. In some examples, the upper surface of the first interlayer insulating layer 140 may be formed on the same plane as the upper surface of the capping pattern 113. The first interlayer insulating layer 140 may include, for example, at least one of silicon oxide, silicon nitride, silicon oxynitride, and a low-k dielectric material. The low-k dielectric material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxy DitertiaryButoxySiloxane (DADBS), TriMethylSilyl Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK™, Amorphous Fluorinated Carbon, silica aerogels, silica xerogels, mesoporous silica, or combinations thereof, but the present invention is not limited thereto.

The gate contact CB may penetrate the capping pattern 113 in the vertical direction DR3 and be connected to the gate electrode G1. In FIG. 4, the gate contact CB is shown to be disposed between the first active pattern 101 and the second active pattern 102, but the present invention is not limited thereto. In some other exemplary embodiments, the gate contact CB may overlap with either the first active pattern 101 or the second active pattern 102 in the vertical direction DR3. The gate contacts CB may include a conductive material.

The second etching stop layer 150 may be disposed on the upper surface of each of the first interlayer insulating layer 140, the capping pattern 113, and the gate contact CB. In FIGS. 2 to 4, the second etching stop layer 150 is shown as being formed as a single layer, but the present invention is not limited thereto. In some other exemplary embodiments, the second etching stop layer 150 may be formed as multiple layers. In some examples, the second etching stop layer 150 may be or include at least one of aluminum oxide, aluminum nitride, hafnium oxide, zirconium oxide, silicon oxide, silicon nitride, silicon oxynitride, or a low-k dielectric material.

The second interlayer insulating layer 160 may be disposed on the second etching stop layer 150. The second interlayer insulating layer 160 may be or include, for example, at least one of silicon oxide, silicon nitride, silicon oxynitride, or a low-k dielectric material. The via V1 may penetrate the second interlayer insulating layer 160 and the second etching stop layer 150 in the vertical direction DR3 to connect to the gate contact CB. The via V1 may be or include a conductive material.

In the semiconductor device according to some exemplary embodiments of the present disclosure, the first and second plurality of nanosheets NW1, NW2 spaced apart in the second horizontal direction DR2 may be surrounded by one gate electrode G1, wherein one of the first and second plurality of nanosheets NW1, NW2 may be utilized as a channel layer of an NMOS transistor and the other of the first and second plurality of nanosheets NW1, NW2 may be utilized as a channel layer of a PMOS transistor. In the semiconductor device according to some exemplary embodiments of the present disclosure, the second width W2 of the second plurality of nanosheets NW2 in the second horizontal direction DR2 may be greater than the first width W1 of the first plurality of nanosheets NW1 in the second horizontal direction DR2, and the second thickness t3 of the second inner spacer 122 in the first horizontal direction DR1 may be smaller than the first thickness t2 of the first inner spacer 121 in the first horizontal direction DR1. In the semiconductor device according to some exemplary embodiments of the present disclosure, the first and second thicknesses t2 and t3 of the first and second inner spacers 121, 122 disposed on the NMOS transistor and the PMOS transistor may be formed differently, which may improve the reliability of the semiconductor device.

Hereinafter, the fabrication method of a semiconductor device according to some exemplary embodiments of the present disclosure will be described with reference to FIGS. 2 to 22.

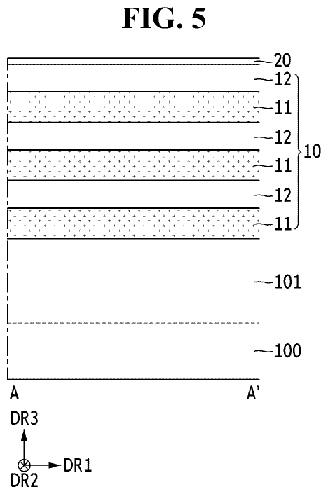

FIGS. 5 to 22 are intermediate stage diagrams for explaining the fabrication method of a semiconductor device according to some exemplary embodiments of the present disclosure.

Referring to FIGS. 5 to 7, a stacked structure 10 may be formed on the substrate 100. The stacked structure 10 may include sacrificial layers 11 and semiconductor layers 12 alternately stacked on the substrate 100. In some examples, the sacrificial layer 11 may be formed at the lowermost portion of the stacked structure 10, and the semiconductor layer 12 may be formed on the uppermost portion of the stacked structure 10. However, the present invention is not limited thereto. In some other exemplary embodiments, the sacrificial layer 11 may also be formed on the uppermost portion of the stacked structure 10. The sacrificial layer 11 may be or include, for example, silicon germanium (SiGe). The semiconductor layer 12 may be, for example, silicon (Si).

Subsequently, a portion of the stacked structure 10 may be etched. While the stacked structure 10 is being etched, a portion of the substrate 100 may also be etched. Through such an etching process, each of the first and second active patterns 101, 102 may be defined beneath the stacked structure 10 on the upper surface of the substrate 100. Each of the first and second active patterns 101, 102 may extend in the first horizontal direction DR1. The second active pattern 102 may be spaced apart from the first active pattern 101 in the second horizontal direction DR2. In some examples, the second width of the second active pattern 102 in the second horizontal direction DR2 may be greater than the first width of the first active pattern 101 in the second horizontal direction DR2.

Subsequently, the field insulating layer 105 may be formed on the upper surface of the substrate 100. The field insulating layer 105 may surround the sidewall of each of the first and second active patterns 101, 102. In some examples, the upper surface of each of the first and second active patterns 101, 102 may be formed higher than the upper surface of the field insulating layer 105. Subsequently, a pad oxide layer 20 may be formed to cover the upper surface of the field insulating layer 105, the exposed sidewall of each of the first and second active patterns 101, 102, and the sidewalls and upper surface of the stacked structure 10. In some examples, the pad oxide layer 20 may be formed conformally. The pad oxide layer 20 may be, for example, silicon oxide (SiO₂).

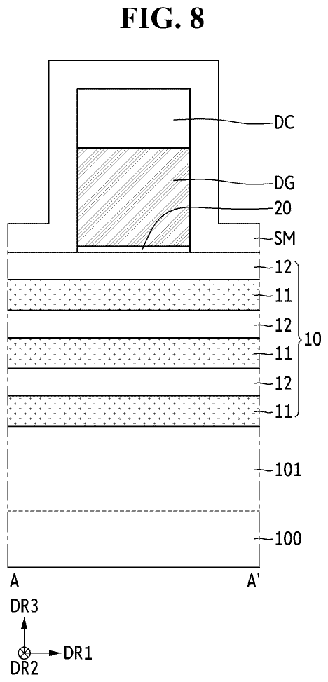

Referring to FIGS. 8 to 10, a dummy gate DG and a dummy capping pattern DC extending in the second horizontal direction DR2 may be formed on the pad oxide layer 20 on the stacked structure 10 and field insulating layer 105. The dummy capping pattern DC may be disposed on the dummy gate DG. While the dummy gate DG and the dummy capping pattern DC are being formed, the remaining pad oxide layer 20 except for the portion that overlaps the dummy gate DG in the vertical direction DR3 on the substrate 100 may be removed.

Subsequently, a spacer material layer SM may be formed to cover the sidewall of the dummy gate DG, the sidewall and upper surface of each of the dummy capping pattern DC, the exposed sidewall and upper surface of the stacked structure 10, and the upper surface of the field insulating layer 105. In some examples, the spacer material layer SM may be formed conformally. The spacer material layer SM may be or include at least one of, for example, silicon nitride (SiN), silicon oxycarbonitride (SiOCN), silicon boron carbonitride (SiBCN), silicon carbonitride (SiCN), silicon oxynitride (SiON), or combinations thereof.

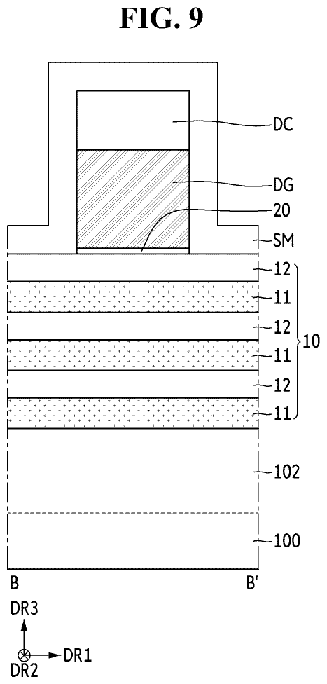

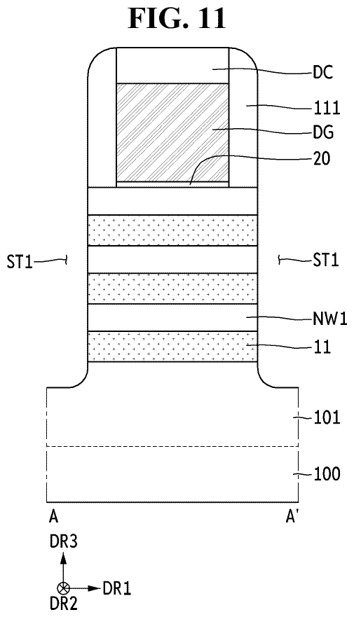

Referring to FIGS. 11 to 13, the stacked structure 10 (see FIGS. 8 and 9) may be etched using the dummy gate DG and dummy capping pattern DC as masks to form the first and second source/drain trenches ST1, ST2. In some examples, the first source/drain trench ST1 may be formed on the first active pattern 101. The second source/drain trench ST2 may be formed on the second active pattern 102. While each of the first and second source/drain trenches ST1, ST2 is being formed, a portion of the spacer material layer SM (see FIGS. 8 and 9) formed on the upper surface of the dummy capping pattern DC and a portion of the dummy capping pattern DC may be etched.

In some examples, after each of the first and second source/drain trenches ST1, ST2 is formed, the spacer material layer SM (see FIGS. 8 and 9) remaining on the sidewall of each of the dummy capping pattern DC and the dummy gate DG may be defined as a gate spacer 111. In some examples, after the first source/drain trench ST1 is formed, the semiconductor layer 12 (see FIG. 8) remaining beneath the dummy gate DG on the first active pattern 101 may be defined as the first plurality of nanosheets NW1. Further, after the second source/drain trench ST2 is formed, the semiconductor layer 12 (see FIG. 9) remaining beneath the dummy gate DG on the second active pattern 102 may be defined as the second plurality of nanosheets NW2.

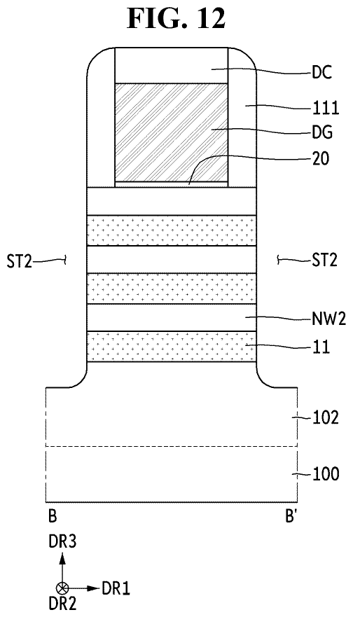

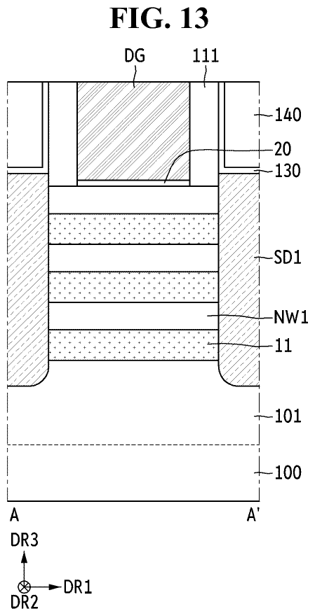

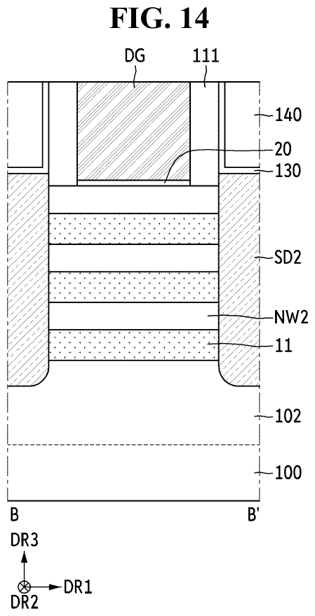

Referring to FIGS. 13 and 14, the first source/drain region SD1 may be formed inside the first source/drain trench ST1 (see FIG. 11). In some examples, the first source/drain region SD1 may be in contact with both of the two sidewalls of each nanosheet of the first plurality of nanosheets NW1 in the first horizontal direction DR1. Further, the first source/drain region SD1 may be in contact with both sidewalls of the sacrificial layer 11 formed on the first active pattern 101 in the first horizontal direction DR1. The second source/drain region SD2 may be formed inside the second source/drain trench ST2 (see FIG. 12). In some examples, the second source/drain region SD2 may be in contact with both of the two sidewalls of each nanosheet of the second plurality of nanosheets NW2 in the first horizontal direction DR1. Further, the second source/drain region SD2 may be in contact with both sidewalls of the sacrificial layer 11 formed on the second active pattern 102 in the first horizontal direction DR1.

Subsequently, the first etching stop layer 130 may be formed on the surface of each of the first and second source/drain regions SD1, SD2 and on the sidewall of the gate spacer 111. Although not shown, the first etching stop layer 130 may also be formed on the upper surface of the field insulating layer 105. In some examples, the first etching stop layer 130 may be formed conformally. Subsequently, the first interlayer insulating layer 140 may be formed on the first etching stop layer 130. Subsequently, through a planarization process, the upper surface of the dummy gate DG may be exposed.

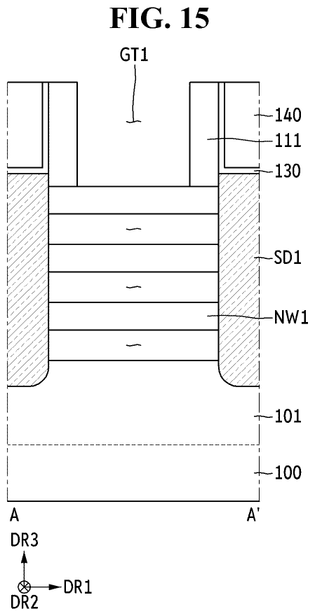

Referring to FIGS. 15 to 17, the dummy gate DG (see FIGS. 13 and 14), the pad oxide layer 20 (see FIGS. 13 and 14), and the sacrificial layer 11 (see FIGS. 13 and 14) may each be etched. In some examples, the portion from which each of the dummy gate DG (see FIGS. 13 and 14), the pad oxide layer 20 (see FIGS. 13 and 14), and the sacrificial layer 11 (see FIGS. 13 and 14) is removed may be defined as the first gate trench GT1.

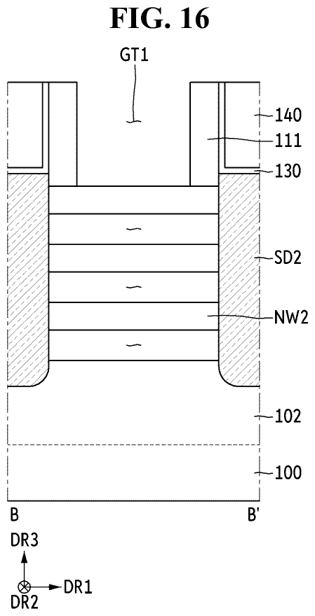

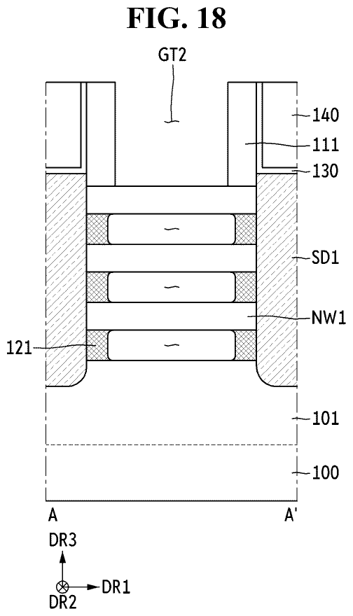

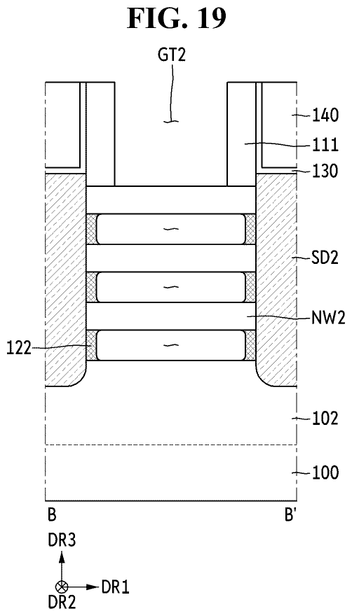

Referring to FIGS. 18 and 19, the first inner spacer 121 that is in contact with the first source/drain region SD1 may be formed inside the first gate trench GT1 (see FIGS. 15 and 16). Further, the second inner spacer 122 that is in contact with the second source/drain region SD2 may be formed inside the first gate trench GT1 (see FIGS. 15 and 16). In some examples, the second thickness t3 of the second inner spacer 122 in the first horizontal direction DR1 may be formed smaller than the first thickness t2 of the first inner spacer 121 in the first horizontal direction DR1. In some examples, inside the first gate trench GT1 (see FIGS. 15 and 16), the remaining region excluding the portion in which the first and second inner spacers 121, 122 are formed may be defined as the second gate trench GT2.

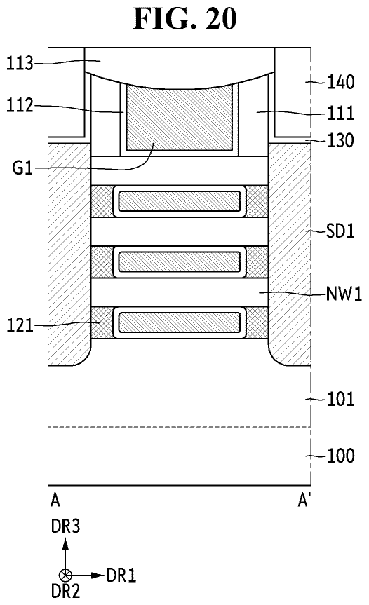

Referring to FIGS. 20 to 22, the gate insulating layer 112, the gate electrode G1, and the capping pattern 113 may be formed sequentially inside the second gate trench GT2 (see FIGS. 18 and 19). In some examples, the gate insulating layer 112 may be in contact with the inner sidewalls of the first and second inner spacers 121, 122 in the first horizontal direction DR1.

Referring to FIGS. 2 to 4, the gate contact CB that penetrates the capping pattern 113 in the vertical direction DR3 and is connected to the gate electrode G1 may be formed. Subsequently, the second etching stop layer 150 and the second interlayer insulating layer 160 may be formed sequentially on the upper surface of each of the first interlayer insulating layer 140, the capping pattern 113, and the gate contact CB. Subsequently, the via V1 that penetrates the second interlayer insulating layer 160 and the second etching stop layer 150 in the vertical direction DR3 and is connected to the gate contact CB may be formed. Through this fabrication process, the semiconductor device shown in FIGS. 2 to 4 may be fabricated.

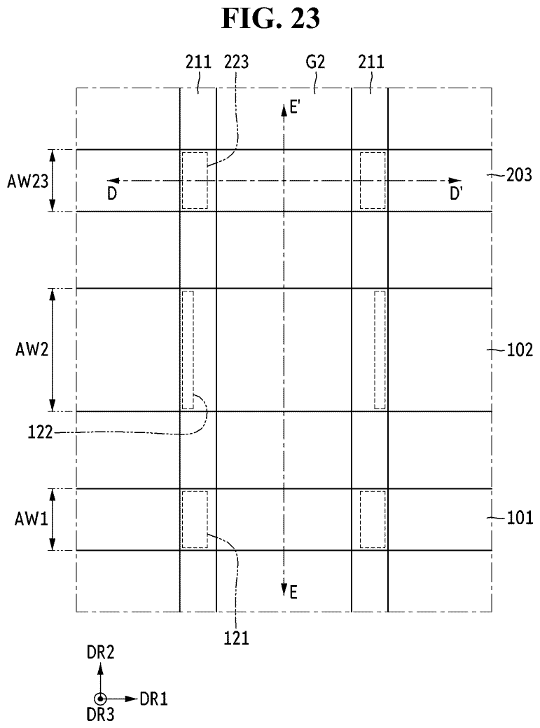

Referring to FIGS. 23 to 25, the semiconductor device according to some other embodiments of the present disclosure will be described. The description will focus on the differences from the semiconductor devices shown in FIGS. 1 to 4.

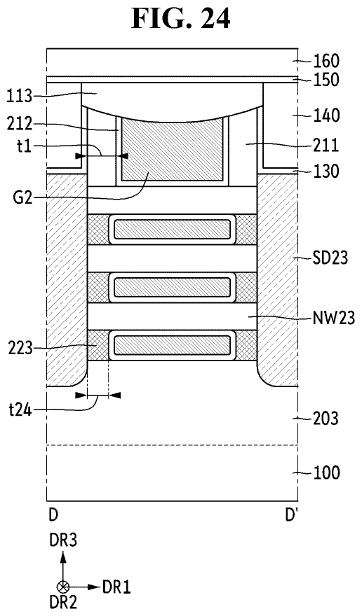

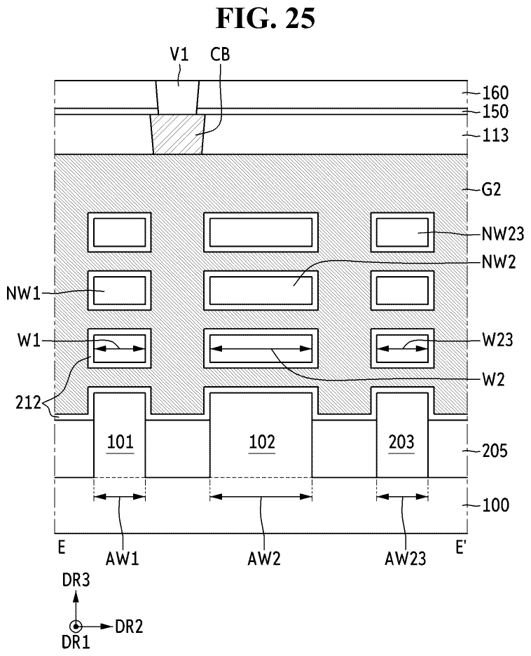

FIG. 23 is a layout diagram for explaining the semiconductor device according to some other exemplary embodiments of the present disclosure. FIG. 24 is a cross-sectional view taken along the line D-D′ of FIG. 23. FIG. 25 is a cross-sectional view taken along the line E-E′ of FIG. 23.

Referring now to FIGS. 23 to 25, the semiconductor device according to some other exemplary embodiments of the present disclosure may include a third active pattern 203, a third plurality of nanosheets NW23, a third source/drain region SD23, and a third inner spacer 223.

In some examples, the third active pattern 203 may extend in the first horizontal direction DR1. In some examples, the third active pattern 203 may be spaced apart from the second active pattern 102 in the second horizontal direction DR2. The second active pattern 102 may be disposed between the first active pattern 101 and the third active pattern 203. The third active pattern 203 may protrude in the vertical direction DR3 from the upper surface of the substrate 100. In some examples, the third active pattern 203 may be part of the substrate 100 or may include an epitaxial layer grown from the substrate 100.

In some examples, the distance in the second horizontal direction DR2 between the third active pattern 203 and the second active pattern 102 may be the same as the distance in the second horizontal direction DR2 between the first active pattern 101 and the second active pattern 102. In some examples, the third width AW23 of the third active pattern 203 in the second horizontal direction DR2 may be smaller than the second width AW2 of the second active pattern 102 in the second horizontal direction DR2. In some examples, the third width AW23 of the third active pattern 203 in the second horizontal direction DR2 may be the same as the first width AW1 of the first active pattern 101 in the second horizontal direction DR2. The field insulating layer 205 may surround the sidewall of each of the first to third active patterns 101, 102, 203 on the upper surface of the substrate 100.

In some examples, the third plurality of nanosheets NW23 may include a plurality of nanosheets stacked and spaced apart from each other in the vertical direction DR3 on the third active pattern 203. The third plurality of nanosheets NW23 may be spaced apart from the second plurality of nanosheets NW2 in the second horizontal direction DR2. In some examples, the third width W23 of the third plurality of nanosheets NW23 in the second horizontal direction DR2 may be smaller than the second width W2 of the second plurality of nanosheets NW2 in the second horizontal direction DR2. In some examples, the third width W23 of the third plurality of nanosheets NW23 in the second horizontal direction DR2 may be the same as the first width W1 of the first plurality of nanosheets NW1 in the second horizontal direction DR2. In some examples, each of the nanosheets included in the third plurality of nanosheets NW23 may be disposed at the same vertical level as each of the nanosheets included in each of the first and second plurality of nanosheets NW1, NW2.

In some examples, the gate electrode G2 may extend in the second horizontal direction DR2 on the first to third active patterns 101, 102, 203 and the field insulating layer 205. The gate electrode G2 may surround each of the first to third plurality of nanosheets NW1, NW2, NW23. In some examples, the gate spacer 211 may extend in the second horizontal direction DR2 along both sidewalls of the gate electrode G2 in the first horizontal direction DR1 on the upper surfaces of the uppermost nanosheets of each of the first to third plurality of nanosheets NW1, NW2, NW23 and the upper surface of the field insulating layer 205. In some examples, the third source/drain region SD23 may be disposed on both of the two sidewalls of the gate electrode G2 in the first horizontal direction DR1 on the third active pattern 203. The third source/drain region SD23 may be in contact with both of the two sidewalls of each nanosheet of the third plurality of nanosheets NW23 in the first horizontal direction DR1.

In some exemplary embodiments, the first plurality of nanosheets NW1, the gate electrode G2, and the first In some examples, the first plurality of nanosheets NW1 may include two sidewalls for each nanosheet of the plurality of nanosheets NW1, and source/drain region SD1 may form an NMOS transistor, the second plurality of nanosheets NW2, the gate electrode G2, and the second source/drain region SD2 may form a PMOS transistor, and the third plurality of nanosheets NW23, the gate electrode G2, and the third source/drain region SD23 may form an NMOS transistor. In some other exemplary embodiments, the first plurality of nanosheets NW1, the gate electrode G2, and the first source/drain region SD1 may form a PMOS transistor, and the second plurality of nanosheets NW2, the gate electrode G2, and second source/drain region SD2 may form an NMOS transistor, and the third plurality of nanosheets NW23, the gate electrode G2, and third source/drain region SD23 may form a PMOS transistor.

In some examples, the third inner spacer 223 may be disposed between the gate electrode G2 and the third source/drain region SD23. In some examples, the third inner spacer 223 may be in contact with the third source/drain region SD23. The third inner spacer 223 may be disposed on both of the two sidewalls of the gate electrode G2 in the first horizontal direction DR1 between the uppermost surface of the third active pattern 203 and the bottom surface of the lowermost nanosheet of the third plurality of nanosheets NW23. The third inner spacer 223 may be disposed on both of the two sidewalls of the gate electrode G2 in the first horizontal direction DR1 between adjacent the third plurality of nanosheets NW23.

In some examples, the third thickness t24 of the third inner spacer 223 in the first horizontal direction DR1 may be smaller than the thickness t1 of the gate spacer 211 disposed on one side of the gate electrode G2 in the first horizontal direction DR1. Thickness t1, as used herein, refers to the thickness of each of the gate spacers in various embodiments (e.g., gate spacers 111, 211, or 311 on a side of gate electrode G1, G2 or G3). In some examples, the third thickness t24 of the third inner spacer 223 in the first horizontal direction DR1 may be greater than the second thickness t3 (see FIG. 3) of the second inner spacer 122 in the first horizontal direction DR1. In some examples, the third thickness t24 of the third inner spacer 223 in the first horizontal direction DR1 may be the same as the first thickness t2 (see FIG. 2) of the first inner spacer 121 in the first horizontal direction DR1. In some examples, the third width of the third inner spacer 223 in the second horizontal direction DR2 may be smaller than the second width of the second inner spacer 122 in the second horizontal direction DR2. In some examples, the third width of the third inner spacer 223 in the second horizontal direction DR2 may be the same as the first width of the first inner spacer 121 in the second horizontal direction DR2.

In some examples, a first portion of the third inner spacer 223 may overlap with the second inner spacer 122 in the second horizontal direction DR2. In some examples, a second portion of the third inner spacer 223 does not overlap with the second inner spacer 122 in the second horizontal direction DR2. In some examples, the third inner spacer 223 may be the same material as each of the first and second inner spacers 121, 122. In some examples, the gate insulating layer 212 may be additionally disposed between the gate electrode G2 and the third active pattern 203. The gate insulating layer 212 may be additionally disposed between the gate electrode G2 and the third plurality of nanosheets NW23. The gate insulating layer 212 may be additionally disposed between the gate electrode G2 and the third inner spacer 223.

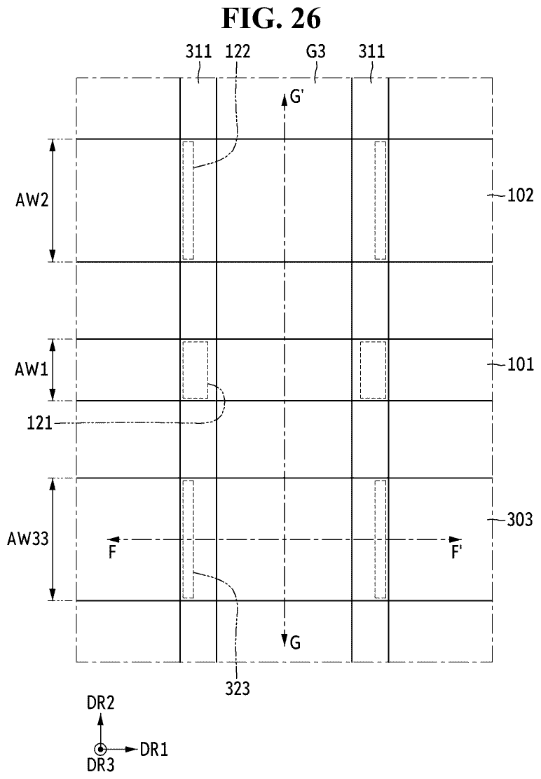

Referring to FIGS. 26 to 28, a semiconductor device according to another several exemplary embodiments of the present disclosure will be described. The description will focus on the differences from the semiconductor device shown in FIGS. 1 to 4.

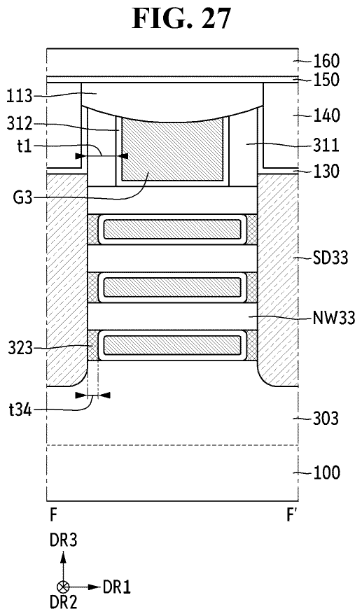

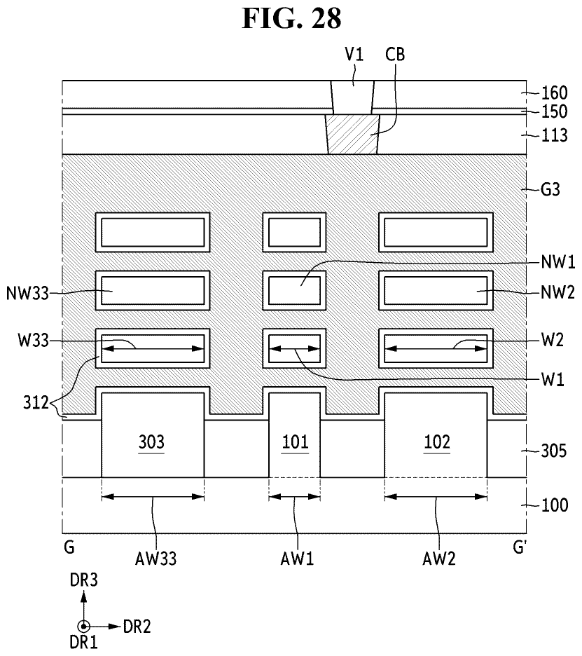

FIG. 26 is a layout diagram for explaining the semiconductor device according to another several exemplary embodiments of the present disclosure. FIG. 27 is a cross-sectional view taken along the line F-F′ of FIG. 26. FIG. 28 is a cross-sectional view taken along the line G-G′ of FIG. 26.

Referring to FIGS. 26 to 28, the semiconductor device according to several other exemplary embodiments of the present disclosure may include the fourth active pattern 303, the fourth plurality of nanosheets NW33, the fourth source/drain region SD33, and the fourth inner spacer 323.

In some examples, the fourth active pattern 303 may extend in the first horizontal direction DR1. In some examples, the fourth active pattern 303 may be spaced apart from the first active pattern 101 in the reverse direction of the second horizontal direction DR2. The first active pattern 101 may be disposed between the fourth active pattern 303 and the second active pattern 102. The fourth active pattern 303 may protrude from the upper surface of the substrate 100 in the vertical direction DR3. In some examples, the fourth active pattern 303 may be part of the substrate 100, or may include an epitaxial layer grown from the substrate 100.

In some examples, the distance in the second horizontal direction DR2 between the fourth active pattern 303 and the first active pattern 101 may be the same as the distance in the second horizontal direction DR2 between the first active pattern 101 and the second active pattern 102. In some examples, the fourth width AW33 of the fourth active pattern 303 in the second horizontal direction DR2 may be greater than the first width AW1 of the first active pattern 101 in the second horizontal direction DR2. In some examples, the fourth width AW33 of the fourth active pattern 303 in the second horizontal direction DR2 may be the same as the second width AW2 of the second active pattern 102 in the second horizontal direction DR2. The field insulating layer 305 may surround the sidewall of each of the first, second and fourth active patterns 101, 102, 303 on the upper surface of the substrate 100.

For example, the fourth plurality of nanosheets NW33 may include a plurality of nanosheets stacked and spaced apart from each other in the vertical direction DR3 on the fourth active pattern 303. The fourth plurality of nanosheets NW33 may be spaced apart from the first plurality of nanosheets NW1 in the reverse direction of the second horizontal direction DR2. In some examples, the fourth width W33 of the fourth plurality of nanosheets NW33 in the second horizontal direction DR2 may be greater than the first width W1 of the first plurality of nanosheets NW1 in the second horizontal direction DR2. In some examples, the fourth width W33 of the fourth plurality of nanosheets NW33 in the second horizontal direction DR2 may be the same as the second width W2 of the second plurality of nanosheets NW2 in the second horizontal direction DR2. In some examples, each of the nanosheets included in the fourth plurality of nanosheets NW33 may be disposed at the same vertical level as each of the nanosheets included in each of the first and second plurality of nanosheets NW1, NW2.

In some examples, the gate electrode G3 may extend in the second horizontal direction DR2 on the first, second and fourth active patterns 101, 102, 303 and the field insulating layer 305. The gate electrode G3 may surround each of the first, second and fourth plurality of nanosheets NW1, NW2, NW33. In some examples, the gate spacer 311 may extend in the second horizontal direction DR2 along both of the two sidewalls of the gate electrode G3 in the first horizontal direction DR1 on the upper surfaces of the uppermost nanosheets of each of the first, second and fourth pluralities of nanosheets NW1, NW2, NW33 and the upper surface of the field insulating layer 305. In some examples, the fourth source/drain region SD33 may be disposed on both of the two sidewalls of the gate electrode G3 in the first horizontal direction DR1 on the fourth active pattern 303. The fourth source/drain region SD33 may be in contact with both of the two sidewalls of each nanosheet of the fourth plurality of nanosheets NW33 in the first horizontal direction DR1.

In some embodiments, the first plurality of nanosheets NW1, the gate electrode G3, and the first source/drain region SD1 form an NMOS transistor, the second plurality of nanosheets NW2, the gate electrode G3, and the second source/drain region SD2 may form a PMOS transistor, and the fourth plurality of nanosheets NW33, the gate electrode G3, and the fourth source/drain region SD33 may form an NMOS transistor. In some other exemplary embodiments, the first plurality of nanosheets NW1, the gate electrode G3, and the first source/drain region SD1 form a PMOS transistor, the second plurality of nanosheets NW2, the gate electrode G3, and the second source/drain region SD2 may form an NMOS transistor, and the fourth plurality of nanosheets NW33, the gate electrode G3, and the fourth source/drain region SD33 may form a PMOS transistor.

In some examples, the fourth inner spacer 323 may be disposed between the gate electrode G3 and the fourth source/drain region SD33. In some examples, the third fourth spacer 323 may be in contact with the fourth source/drain region SD33. The fourth inner spacer 323 may be disposed on both of the two sidewalls of the gate electrode G3 in the first horizontal direction DR1 between the uppermost surface of the fourth active pattern 303 and the bottom surface of the lowermost nanosheet of the fourth plurality of nanosheets NW33. The fourth inner spacer 323 may be disposed on both of the two sidewalls of the gate electrode G3 in the first horizontal direction DR1 between adjacent the fourth plurality of nanosheets NW33.

In some examples, the fourth thickness t34 of the fourth inner spacer 323 in the first horizontal direction DR1 may be smaller than the thickness t1 in the first horizontal direction DR1 of the gate spacer 311 disposed on one side of the gate electrode G3. In some examples, the fourth thickness t34 of the fourth inner spacer 323 in the first horizontal direction DR1 may be smaller than the first thickness t2 (see FIG. 2) of the first inner spacer 121 in the first horizontal direction DR1. In some examples, the fourth thickness t34 of the fourth inner spacer 323 in the first horizontal direction DR1 may be the same as the thickness t3 (see FIG. 3) of the second inner spacer 122 in the first horizontal direction DR1. In some examples, the fourth width of the fourth inner spacer 323 in the second horizontal direction DR2 may be greater than the first width of the first inner spacer 121 in the second horizontal direction DR2. In some examples, the fourth width of the fourth inner spacer 323 in the second horizontal direction DR2 may be the same as the second width of the second inner spacer 122 in the second horizontal direction DR2.

In some examples, a portion of the first inner spacer 121 may overlap with the fourth inner spacer 323 in the second horizontal direction DR2. In some examples, another portion of the first inner spacer 121 may not overlap with the fourth inner spacer 323 in the second horizontal direction DR2. In some examples, the fourth inner spacer 323 may be the same material as each of the first and second inner spacers 121, 122. In some examples, the gate insulating layer 312 may be disposed additionally between the gate electrode G3 and the fourth active pattern 303. The gate insulating layer 312 may be disposed additionally between the gate electrode G3 and the fourth plurality of nanosheets NW33. The gate insulating layer 312 may be disposed additionally between the gate electrode G3 and the fourth inner spacer 323.

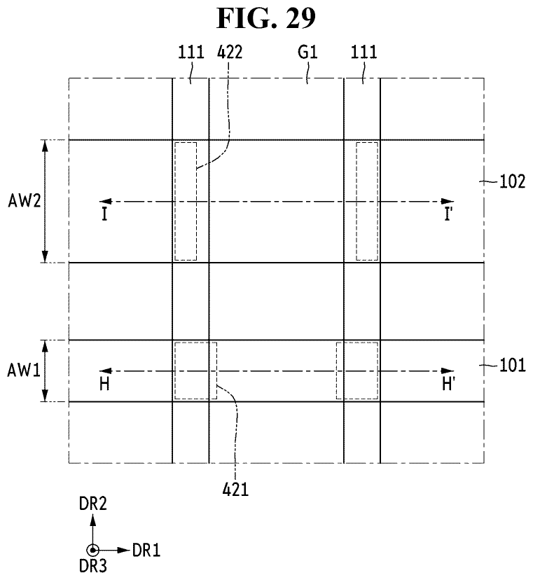

Hereinafter, a semiconductor device according to some other embodiments of the present disclosure will be described with reference to FIGS. 29 to 31. The description will focus on the differences from the semiconductor device shown in FIGS. 1 to 4.

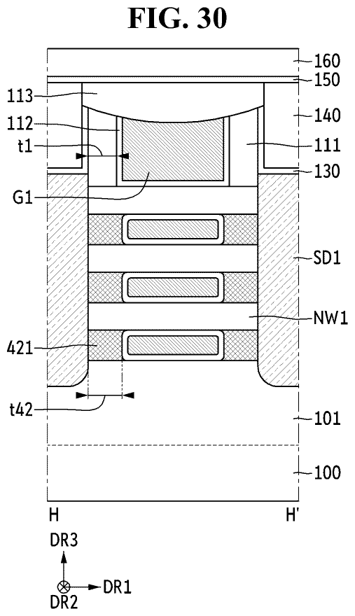

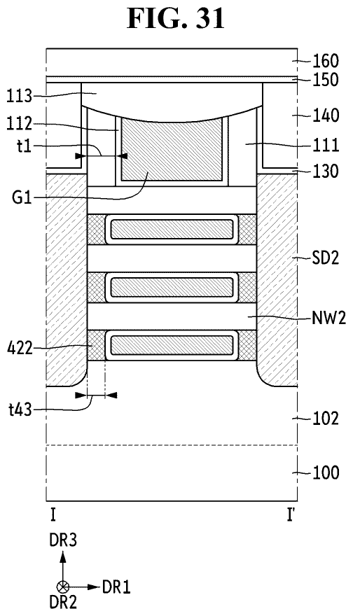

FIG. 29 is a layout diagram for explaining a semiconductor device according to another several exemplary embodiments of the present disclosure. FIG. 30 is a cross-sectional view taken along the line H-H′ of FIG. 29. FIG. 31 is a cross-sectional view taken along the line I-I′ of FIG. 29.

Referring to FIGS. 29 to 31, a semiconductor device according to some other exemplary embodiments of the present disclosure may have the fifth thickness t42 of the fifth inner spacer 421 in the first horizontal direction DR1 greater than the thickness t1 of the gate spacer 111 in the first horizontal direction DR1.

In some examples, the fifth thickness t42 of the fifth inner spacer 421 in the first horizontal direction DR1 may be greater than the sixth thickness t43 of the sixth inner spacer 422 in the first horizontal direction DR1. In some examples, the sixth thickness t43 of the sixth inner spacer 422 in the first horizontal direction DR1 may be smaller than the thickness t1 of the gate spacer 111 in the first horizontal direction DR1.

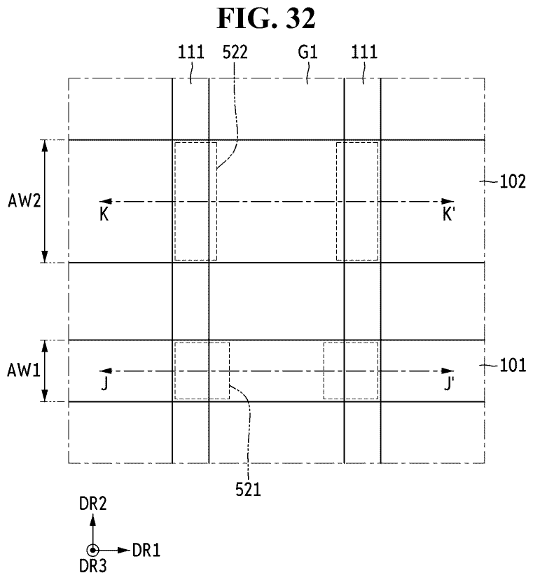

Hereinafter, a semiconductor device according to some other exemplary embodiments of the present disclosure will be described with reference to FIGS. 32 to 34. The description will focus on the differences from the semiconductor device shown in FIGS. 1 to 4.

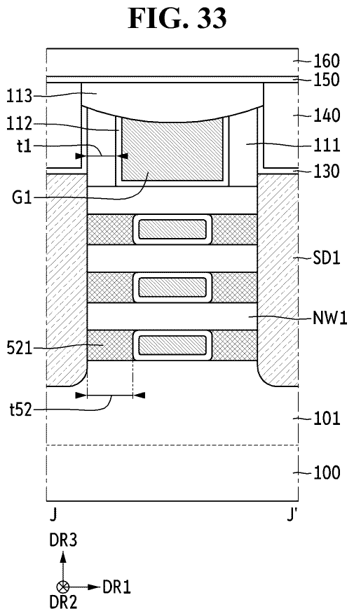

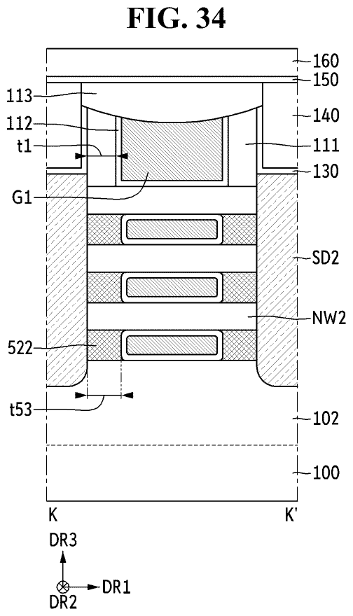

FIG. 32 is a layout diagram for explaining a semiconductor device according to another several exemplary embodiments of the present disclosure. FIG. 33 is a cross-sectional view taken along the line J-J′ of FIG. 32. FIG. 34 is a cross-sectional view taken along the line K-K′ of FIG. 32.

Referring to FIGS. 32 to 34, a semiconductor device according to still some other exemplary embodiments of the present disclosure may have the seventh thickness t53 of the seventh inner spacer 522 in the first horizontal direction DR1 greater than the thickness t1 of the gate spacer 111 in the first horizontal direction DR1.

In some examples, the eighth thickness t52 of the eighth inner spacer 521 in the first horizontal direction DR1 may be greater than the seventh thickness t53 in the first horizontal direction DR1 of the seventh inner spacer 522. In some examples, the eighth thickness t52 of the eighth inner spacer 521 in the first horizontal direction DR1 may be greater than the thickness t1 of the gate spacer 111 in the first horizontal direction DR1.

While exemplary embodiments according to the present disclosure have been described above with reference to the accompanying drawings, it will be understood that the present invention is not limited to the above embodiments and may be fabricated in a variety of different forms, and those of ordinary skill in the art to which the present disclosure belongs, may recognize that it may be implemented in other specific forms without changing the technical idea or essential features of the present disclosure. Therefore, it should be understood that the above-described embodiments are exemplary in all respects and not restrictive.

What is claimed is:

1. A semiconductor device comprising:
a substrate;
a first active pattern extending in a first horizontal direction on the substrate;
a second active pattern extending in the first horizontal direction on the substrate, the second active pattern being spaced apart from the first active pattern in a second horizontal direction different from the first horizontal direction, a second width of the second active pattern in the second horizontal direction being greater than a first width of the first active pattern in the second horizontal direction,
a first plurality of nanosheets, each nanosheet of the first plurality of nanosheets being stacked and spaced apart from each other in a vertical direction on the first active pattern,
a second plurality of nanosheets, each nanosheet of the second plurality of nanosheets being spaced apart from each other in the vertical direction on the second active pattern, a second width of each nanosheet of the second plurality of nanosheets in the second horizontal direction being greater than a first width of each nanosheet of the first plurality of nanosheets in the second horizontal direction;
a gate electrode extending in the second horizontal direction on the first and second active patterns, the gate electrode extending surrounding each nanosheet of the first plurality of nanosheets and each nanosheet of the second plurality of nanosheets, the gate electrode having two sidewalls;
a first inner spacer disposed on both of the two sidewalls of the gate electrode in the first horizontal direction between adjacent nanosheets of the first plurality of nanosheets; and
a second inner spacer disposed on both of the two sidewalls of the gate electrode in the first horizontal direction between adjacent nanosheets of the second plurality of nanosheets, a second thickness of the second inner spacer in the first horizontal direction being smaller than a first thickness of the first inner spacer in the first horizontal direction.

2. The semiconductor device of claim 1, wherein a portion of the first inner spacer overlaps with the second inner spacer in the second horizontal direction, and another portion of the first inner spacer does not overlap with the second inner spacer in the second horizontal direction.

3. The semiconductor device of claim 1, wherein a second width of the second inner spacer in the second horizontal direction is greater than a first width of the first inner spacer in the second horizontal direction.

4. The semiconductor device of claim 1, wherein a second width of the gate electrode in the first horizontal direction between adjacent nanosheets of the second plurality of nanosheets is greater than a first width of the gate electrode in the first horizontal direction between adjacent nanosheets of the first plurality of nanosheets.

5. The semiconductor device of claim 1, wherein the second inner spacer comprises a plurality of second inner spacers and the first inner spacer comprises a plurality of first inner spacers, wherein a second width in the first horizontal direction between second inner spacers of the plurality of second inner spacers is greater than a first width in the first horizontal direction between first inner spacers of the plurality of first inner spacers.

6. The semiconductor device of claim 1, further comprising:
a gate spacer disposed on both of the two sidewalls of the gate electrode in the first horizontal direction on a first upper surface of an uppermost nanosheet of the first plurality of nanosheets and on a second upper surface of an uppermost nanosheet of the second plurality of nanosheets,
wherein the second thickness of the second inner spacer in the first horizontal direction is smaller than a thickness of the gate spacer in the first horizontal direction.

7. The semiconductor device of claim 1, further comprising:
a gate spacer disposed on both of the two sidewalls of the gate electrode in the first horizontal direction on a first upper surface of an uppermost nanosheet of the first plurality of nanosheets and on a second upper surface of an uppermost nanosheet of the second plurality of nanosheets,
wherein the first thickness of the first inner spacer in the first horizontal direction is smaller than a thickness of the gate spacer in the first horizontal direction.

8. The semiconductor device of claim 1, wherein the first plurality of nanosheets and the gate electrode form an NMOS transistor, and the second plurality of nanosheets and the gate electrode form a PMOS transistor.

9. The semiconductor device of claim 1, further comprising:
a third active pattern extending in the first horizontal direction on the substrate, the third active pattern being spaced apart from the second active pattern in the second horizontal direction, a third width of the third active pattern in the second horizontal direction being smaller than the second width of the second active pattern in the second horizontal direction;
a third plurality of nanosheets, each nanosheet of the third plurality of nanosheets being stacked and spaced apart from each other in the vertical direction on the third active pattern, a third width of each nanosheet of the third plurality of nanosheets in the second horizontal direction being smaller than the second width of each nanosheet of the second plurality of nanosheets in the second horizontal direction, the third plurality of nanosheets being surrounded by the gate electrode; and
a third inner spacer disposed on both of the two sidewalls of the gate electrode in the first horizontal direction between adjacent nanosheets of the third plurality of nanosheets, a third thickness of the third inner spacer in the first horizontal direction being greater than the second thickness of the second inner spacer in the first horizontal direction.

10. The semiconductor device of claim 9, wherein the third width of the third active pattern in the second horizontal direction is the same as the first width of the first active pattern in the second horizontal direction,
wherein the third width of each nanosheet of the third plurality of nanosheets in the second horizontal direction is the same as the first width of each nanosheet of the first plurality of nanosheets in the second horizontal direction, and
wherein the third thickness of the third inner spacer in the first horizontal direction is the same as the first thickness of the first inner spacer in the first horizontal direction.

11. The semiconductor device of claim 1, further comprising:
a third active pattern extending in the first horizontal direction on the substrate, the third active pattern being spaced apart from the first active pattern in a reverse direction of the second horizontal direction, a third width of the third active pattern in the second horizontal direction greater than the first width of the first active pattern in the second horizontal direction;
a third plurality of nanosheets, each nanosheet of the third plurality of nanosheets being spaced apart from each other in the vertical direction on the third active pattern, a third width of each nanosheet of the third plurality of nanosheets in the second horizontal direction being greater than the first width of each nanosheet of the first plurality of nanosheets in the second horizontal direction, the third plurality of nanosheets being surrounded by the gate electrode; and
a third inner spacer disposed on both of the two sidewalls of the gate electrode in the first horizontal direction between adjacent nanosheets of the third plurality of nanosheets, a third thickness of the third inner spacer in the first horizontal direction being smaller than the first thickness of the first inner spacer in the first horizontal direction.

12. The semiconductor device of claim 11, wherein the third width of the third active pattern in the second horizontal direction is the same as the second width of the second active pattern in the second horizontal direction,
wherein the third width of each nanosheet of the third plurality of nanosheets in the second horizontal direction is the same as the second width of each nanosheet of the second plurality of nanosheets in the second horizontal direction, and
wherein the third thickness of the third inner spacer in the first horizontal direction is the same as the second thickness of the second inner spacer in the first horizontal direction.

13. A semiconductor device comprising,
a substrate;
a first active pattern extending in a first horizontal direction on the substrate;
a second active pattern extending in the first horizontal direction on the substrate, the second active pattern being spaced apart from the first active pattern in a second horizontal direction different from the first horizontal direction,
a first plurality of nanosheets, each nanosheet of the first plurality of nanosheets being stacked and spaced apart from each other in a vertical direction on the first active pattern, each nanosheet of the first plurality of nanosheets having two sidewalls;
a second plurality of nanosheets, each nanosheet of the second plurality of nanosheets being stacked and spaced apart from each other in the vertical direction on the second active pattern, a second width of each nanosheet of the second plurality of nanosheets in the second horizontal direction being greater than a first width of each nanosheet of the first plurality of nanosheets in the second horizontal direction, each nanosheet of the second plurality of nanosheets having two sidewalls;
a gate electrode extending in the second horizontal direction on the first and second active patterns, the gate electrode surrounding each nanosheet of the first plurality of nanosheets and each nanosheet of the second plurality of nanosheets, the gate electrode having two sidewalls;
a first source/drain region being in contact with both of the two sidewalls in the first horizontal direction of each nanosheet of the first plurality of nanosheets on the first active pattern;
a second source/drain region being in contact with both of the two sidewalls in the first horizontal direction of each nanosheet of the second plurality of nanosheets on the second active pattern;
a first inner spacer disposed between the gate electrode and the first source/drain region; and
a second inner spacer disposed between the gate electrode and the second source/drain region,
wherein a first portion of the first inner spacer overlaps with the second inner spacer in the second horizontal direction, and a second portion of the first inner spacer does not overlap with the second inner spacer in the second horizontal direction.

14. The semiconductor device of claim 13, wherein a second thickness of the second inner spacer in the first horizontal direction is smaller than a first thickness of the first inner spacer in the first horizontal direction.

15. The semiconductor device of claim 13, wherein a second width of the second source/drain region in the second horizontal direction is greater than a first width of the first source/drain region in the second horizontal direction.

16. The semiconductor device of claim 13, wherein the first plurality of nanosheets and the gate electrode form a PMOS transistor, and the second plurality of nanosheets and the gate electrode form an NMOS transistor.

17. The semiconductor device of claim 13, further comprising:
a third active pattern extending in the first horizontal direction on the substrate, the third active pattern being spaced apart from the second active pattern in the second horizontal direction;
a third plurality of nanosheets, each nanosheet of the third plurality of nanosheets being stacked and spaced apart from each other in the vertical direction on the third active pattern, a third width of the third plurality of nanosheets in the second horizontal direction being smaller than the second width of the second plurality of nanosheets in the second horizontal direction, each nanosheet of the third plurality of nanosheets being surrounded by the gate electrode, each nanosheet of the third plurality of nanosheets having two sidewalls:
a third source/drain region being in contact with both of the two sidewalls in the first horizontal direction of each nanosheet of the third plurality of nanosheets on the third active pattern; and
a third inner spacer disposed between the gate electrode and the third source/drain region,
wherein a first portion of the third inner spacer overlaps with the second inner spacer in the second horizontal direction, and a second portion of the third inner spacer does not overlap with the second inner spacer in the second horizontal direction.

18. The semiconductor device of claim 13, further comprising:
a third active pattern extending in the first horizontal direction on the substrate, the third active pattern being spaced apart from the first active pattern in a reverse direction of the second horizontal direction;
a third plurality of nanosheets, each nanosheet of the third plurality of nanosheets being stacked and spaced apart from each other in the vertical direction on the third active pattern, a third width of the third plurality of nanosheets in the second horizontal direction being greater than the first width of the first plurality of nanosheets in the second horizontal direction, each nanosheet of the third plurality of nanosheets being surrounded by the gate electrode, each nanosheet of the third plurality of nanosheets having two sidewalls;
a third source/drain region being in contact with both of the two sidewalls in the first horizontal direction of each nanosheet of the third plurality of nanosheets on the third active pattern, and
a third inner spacer disposed between the gate electrode and the third source/drain region, wherein a third portion of the first inner spacer overlaps with the third inner spacer in the second horizontal direction, and a fourth portion of the first inner spacer does not overlap with the third inner spacer in the second horizontal direction.

19. The semiconductor device of claim 13, further comprising:
a gate spacer disposed on both of the two sidewalls in the first horizontal direction of the gate electrode on a first upper surface of an uppermost nanosheet of the first plurality of nanosheets and on a second upper surface of an uppermost nanosheet of the second plurality of nanosheets,
wherein a second thickness of the second inner spacer in the first horizontal direction is greater than a thickness of the gate spacer in the first horizontal direction.

20. A semiconductor device comprising:
a substrate;
a first active pattern extending in a first horizontal direction on the substrate,
a second active pattern extending in the first horizontal direction on the substrate, the second active pattern being spaced apart from the first active pattern in a second horizontal direction different from the first horizontal direction, a second width of the second active pattern in the second horizontal direction greater than a first width of the first active pattern in the second horizontal direction,
a first plurality of nanosheets, each nanosheet of the first plurality of nanosheets being stacked and spaced apart from each other in a vertical direction on the first active pattern, each nanosheet of the first plurality of nanosheets having two sidewalls;
a second plurality of nanosheets, each nanosheet of the second plurality of nanosheets being stacked and spaced apart from each other in the vertical direction on the second active pattern, a second width of each nanosheet of the second plurality of nanosheets in the second horizontal direction being greater than a first width of each nanosheet of the first plurality of nanosheets in the second horizontal direction, each nanosheet of the second plurality of nanosheets having two sidewalls;
a gate electrode extending in the second horizontal direction on the first and second active patterns, the gate electrode surrounding each nanosheet of the first plurality of nanosheets and each nanosheet of the second plurality of nanosheets;
a first source/drain region being in contact with both of the two sidewalls in the first horizontal direction of each nanosheet of the first plurality of nanosheets on the first active pattern;
a second source/drain region being in contact with both of the two sidewalls in the first horizontal direction of each nanosheet of the second plurality of nanosheets on the second active pattern;
a first inner spacer disposed between the gate electrode and the first source/drain region;
a second inner spacer disposed between the gate electrode and the second source/drain region, a second thickness of the second inner spacer in the first horizontal direction being smaller than a first thickness of the first inner spacer in the first horizontal direction, a second width of the second inner spacer in the second horizontal direction being greater than a first width of the first inner spacer in the second horizontal direction; and
a gate spacer disposed on both of the two sidewalls in the first horizontal direction of the gate electrode on a first upper surface of an uppermost nanosheet of the first plurality of nanosheets and on a second upper surface of an uppermost nanosheet of and the second plurality of nanosheets,
wherein the first and second thicknesses of each of the first and second inner spacers in the first horizontal direction are each smaller than a thickness of the gate spacer in the first horizontal direction, and
wherein a first portion of the first inner spacer overlaps with the second inner spacer in the second horizontal direction, and a second portion of the first inner spacer does not overlap with the second inner spacer in the second horizontal direction.
